(19) United States
(12) Patent Application Publication
(10) Pub. No.: US 2021/0007513 A1
(43) Pub. Date: Jan. 14, 2021

(54) SHELF FOR USE IN ELECTRONIC READING APPLICATIONS

(71) Applicant: SATO HOLDINGS KABUSHIKI KAISHA, Tokyo (JP)

(72) Inventors: Graham Murdoch, St Peters (AU); Ganesh Nagendra, St Peters (AU)

(73) Assignee: SATO HOLDINGS KABUSHIKI KAISHA, Tokyo (JP)

(21) Appl. No.: 16/980,597

(22) PCT Filed: Mar. 14, 2019
(86) PCT No.: PCT/IB2019/052059

§ 371 Date: Sep. 14, 2020

(30) Foreign Application Priority Data
Mar. 15, 2018 (AU) 2018900846

(51) Int. Cl. A47F 5/00; H05K 1/18; G06K 19/07

(52) U.S. Cl. CPC A47F 5/0043; H05K 2201/10098; G06K 19/0723; H05K 1/181

(57) ABSTRACT

A shelf (100) for use in electronic reading applications includes a printed circuit board (PCB) (102) and a shelf member (110). The PCB carries a plurality of electronic components (104) which define a circuit board topography having relief features standing proud of a surface (106) of the PCB. The shelf member (110) has a first side (112) and an opposed, second side (114). The second side of the shelf member has recesses (116) corresponding to a negative of the circuit board topography, and the surface (106) of the PCB is attached to the second side (114) of the shelf member so that the electronic components (104) are received within the recesses (116) of the shelf member (110).

### TECHNICAL FIELD

The present disclosure relates, generally, to inventory tracking and other electronic reading applications and, more particularly, to a shelf and method of manufacturing a shelf for use in electronic reading applications.

### CROSS-REFERENCE TO RELATED APPLICATIONS

The present application claims priority from Australian Provisional Patent Application No 2018900846 filed on 15 Mar. 2018, the contents of which are incorporated herein by reference.

### BACKGROUND

Radio-frequency identification (RFID) technology can be used to easily and accurately track items labelled with RFID labels by using RFID readers. In one example, a hand-held reader may be passed close by items held within a storage container, and the hand-held reader will read the RFID labels of the items. In another example, the storage container itself may have an RFID reader or antenna incorporated into the container so that items place within the container may be read. For example, a shelf of a cabinet may be provided with the RFID antenna of an RFID reader so that items placed on the shelf may be identified using the RFID antenna of the shelf.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

### SUMMARY

In one aspect there is provided a shelf for use in electronic reading applications, the shelf including: a printed circuit board (PCB), the PCB carrying a plurality of electronic components which define a circuit board topography having relief features standing proud of a surface of the PCB; and a shelf member having a first side and an opposed, second side, wherein the second side of the shelf member has recesses corresponding to a negative of the circuit board topography, wherein the surface of the PCB is attached to the second side of the shelf member so that the electronic components are received within the recesses of the shelf member.

The recesses may be formed using subtractive manufacturing based on the negative of the circuit board topography.

The PCB may include an RFID antenna.

The shelf may further include a protective layer, wherein the PCB is sandwiched between the shelf member and the protective layer.

The shelf member may include at least one of: a compact laminate material, a thermosetting plastic material, a thermoplastic.

In another aspect there is provided a shelf member for use with a printed circuit board (PCB) carrying a plurality of electronic components which define a circuit board topography having relief features standing proud of a surface of the PCB, the shelf member having a first side and an opposed, second side, wherein the second side of the shelf member has recesses corresponding to a negative of the circuit board topography, and wherein the second side of the shelf member is configured to be attached to the surface of the PCB so that the electronic components are received within the recesses of the shelf member.

The recesses may be formed using subtractive manufacturing based on the negative of the circuit board topography.

The shelf member may include a compact laminate material, and wherein the subtractive manufacturing includes machining of the compact laminate material.

The shelf member may include a thermosetting plastic material, and wherein the subtractive manufacturing includes machining of the thermosetting plastic material.

The shelf member may include a thermoplastic material, and wherein the subtractive manufacturing includes machining of the thermoplastic material.

The PCB may be sandwiched between the shelf member and a protective layer.

In another aspect there is provided a method of manufacturing a shelf member for use in electronic reading applications, the method including: providing a circuit board topography having relief features defined by a plurality of electronic components carried by a printed circuit board (PCB) and standing proud of a surface of the PCB; providing a shelf member blank having a pair of opposed surfaces; and working one of the surfaces to form recesses corresponding to a negative of the circuit board topography so that the plurality of electronic components are receivable within the recesses of the shelf member.

The working may include subtractive manufacturing of the one of the surfaces based on the circuit board topography.

In another aspect there is provided a method of manufacturing a shelf for use in electronic reading applications, the method including: providing a printed circuit board (PCB), the PCB carrying a plurality of electronic components which define a circuit board topography having relief features standing proud of a surface of the PCB; providing a shelf member having a first side and an opposed, second side, wherein the second side of the shelf member has recesses corresponding to a negative of the circuit board topography; and marrying the surface of the PCB to the second side of the shelf member so that the electronic components are received within the recesses of the shelf member.

The PCB may include an RFID antenna.

The shelf member may include at least one of: a compact laminate material, a thermosetting plastic material, and a thermoplastic material.

The method may further include: providing a shelf member blank having a pair of opposed surfaces; and working one of the surfaces to form the recesses

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the disclosure are now described by way of example with reference to the accompanying drawings in which:

FIG. 1A is a schematic representation of an exploded view of an embodiment of a shelf for use in electronic reading applications;

FIG. 1B is a schematic representation of the shelf of FIG. 1A once assembled;

FIG. 1C is a schematic representation of an exploded view of another embodiment of a shelf for use in electronic reading applications;

FIG. 1D is a schematic representation of the shelf of FIG. 1C once assembled;

FIG. 1E is a schematic representation of an exploded view of yet another embodiment of a shelf for use in electronic reading applications;

FIG. 1F is a schematic representation of the shelf of FIG. 1E once assembled;

FIG. 2A is a perspective view of an exemplary printed circuit board (PCB) together with a shelf member that form part of the assembled shelf of FIG. 1B;

FIG. 2B is a perspective view of a PCB carrying electronic components;

FIG. 2C is a perspective view of an exemplary shelf member having recesses formed to receive the electronic components of the PCB illustrated in FIG. 2B; and

FIG. 3 is a flow chart of an embodiment of a method of manufacturing a shelf for use in electronic reading applications.

In the drawings, like reference numerals designate similar parts.

### DESCRIPTION OF EMBODIMENTS

Plastic or laminated shelves that incorporate some or all of an RFID reader's antenna(s) and electronics, typically include a hollow area within the shelf to house and protect the reader electronics. The hollow shelf is typically manufactured using injection moulding. The tooling for injection moulding is very costly, so that any changes to the design of the shelf may result in costly changes to the manufacturing process. If the RFID antenna design changes and the required hollow area within the shelf needs to change, a costly change to the machine tooling may be required. To avoid the costs of injection moulding tooling, the solution proposed herein is to use subtractive manufacturing to remove the profile of the components on the antenna circuit board from the shelf material.

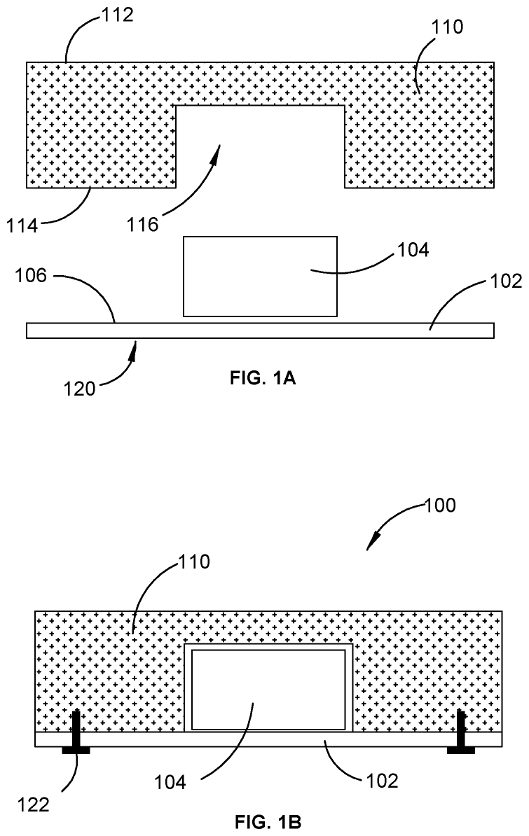

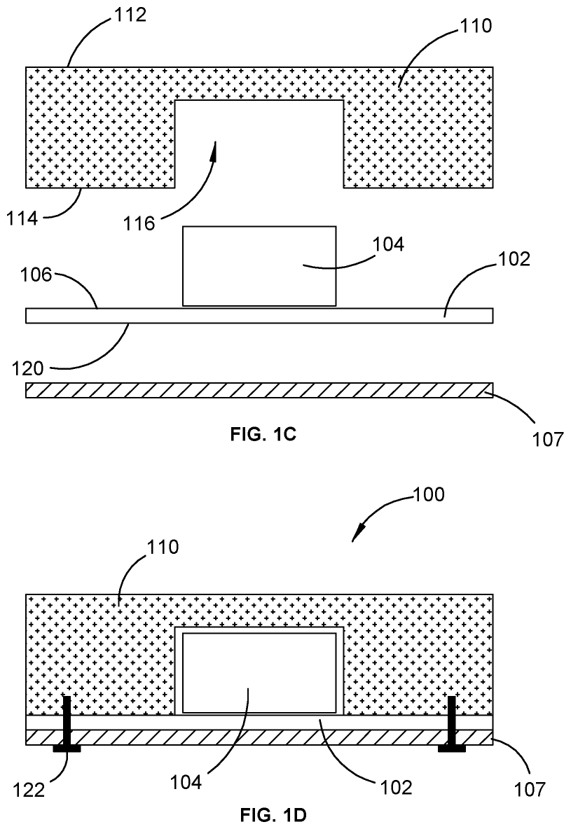

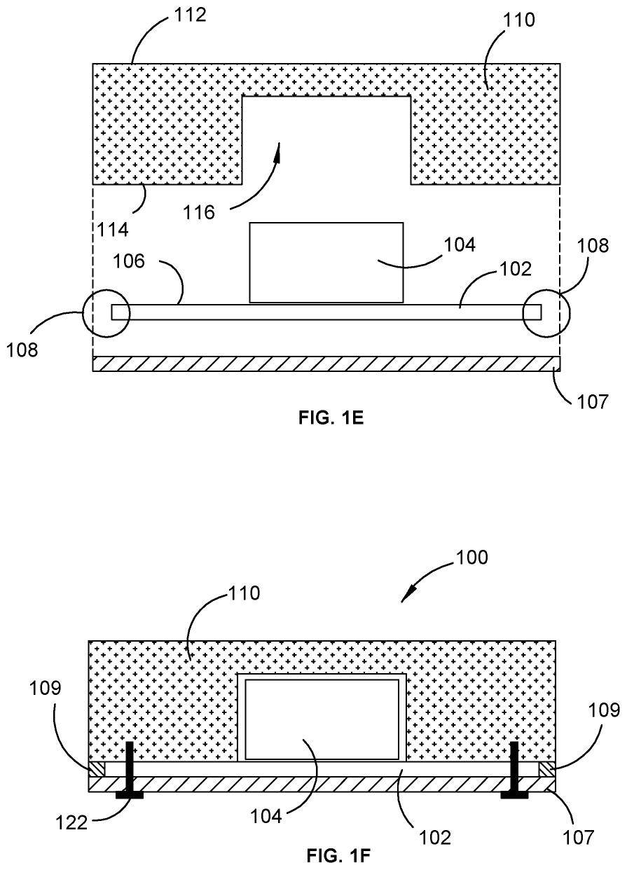

Referring to FIG. 1A and FIG. 1B of the drawings, an embodiment of a shelf 100 for use in electronic reading applications, is in the form of a shelf assembly and includes a printed circuit board (PCB) 102. The PCB 102 carries a plurality of electronic components 104 which define a circuit board topography that has relief features standing proud of a surface 106 of the PCB 102. The shelf 100 has a shelf member 110 having a first side 112 and an opposed, second side 114. The second side 114 of the shelf member 110 has recesses 116 corresponding to a negative of the circuit board topography. The surface 106 of the PCB 102 is attached to the second side 114 of the shelf member 110 so that the electronic components 104 are received within the recesses 116 of the shelf member 110. In this way the shelf member 110 acts as a lid over the PCB 102, the surface of the second side 114 of the shelf member 110 resting against or held close to the surface 106 of the PCB 102, with the recesses 116 accommodating electronic components 104 of various shapes and sizes when the shelf member 110 and PCB 102 are attached together to form a shelf assembly.

In one embodiment the PCB 102 forms part of an electronic reader, for example, the PCB 102 includes RFID antenna electronics. It will be appreciated, however, that the PCB 102 may hold electronic components for other applications.

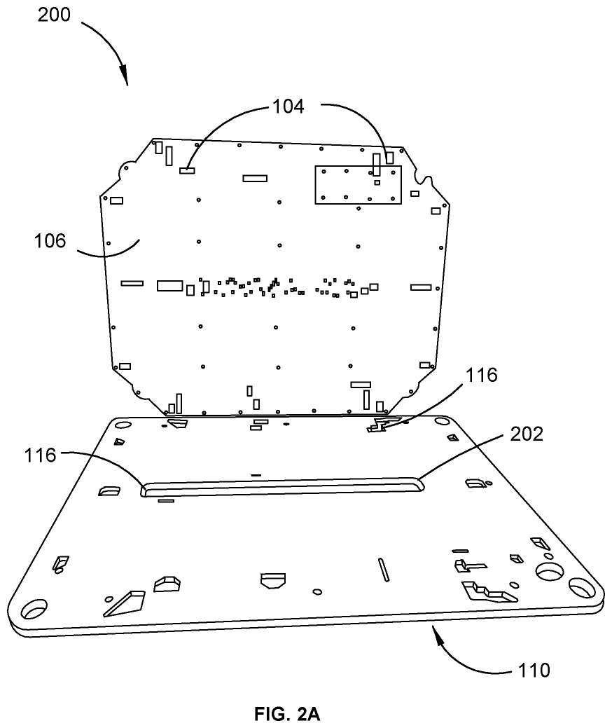

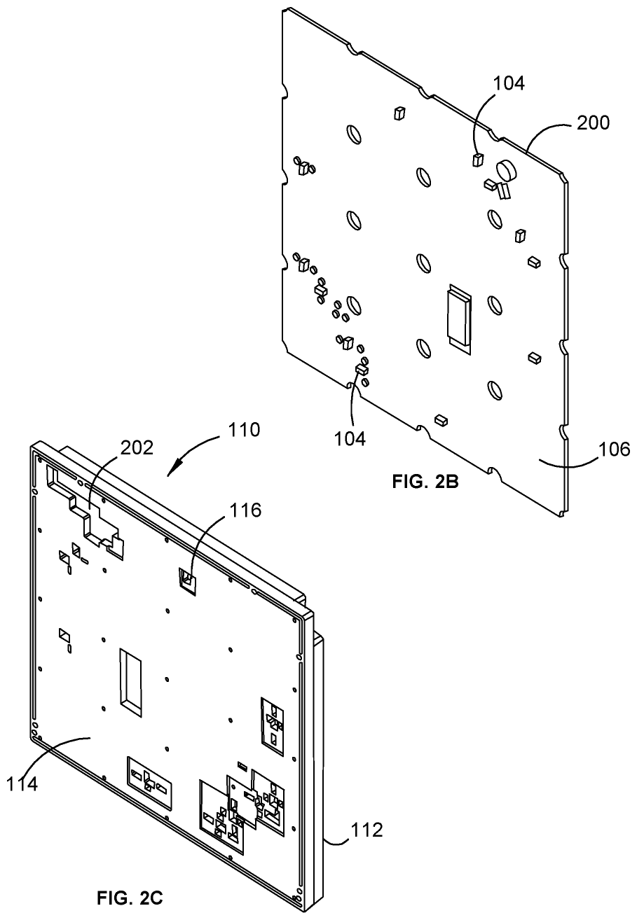

The electronic components 104 define a circuit board topography having relief features standing proud of the surface 106 of the PCB 102, as can be seen in more detail in FIG. 2A-2C. FIG. 2A shows an example of an RFID antenna circuit board 200, with several relatively small electronic components 104 present on the surface 106 of the RFID antenna circuit board 200. Because the electronic components 104 are small, the relief features that form the topography of the circuit board are small, so that the recesses 116 required to receive the components 104 are also relatively small.

In some embodiments the recesses 116 may be shaped to match the negative of the circuit board topography. In other embodiments as illustrated in FIG. 2A and FIG. 2C, the recesses 116 correspond to the negative of the circuit board topography by being shaped to form a containing structure 202 that forms an envelope around portions of the negative of the circuit board topography. Using this type of containing structure 202 simplifies the machining process for complex topographies.

The recesses 116 and/or containing structures 202 are formed to match the topography of the relief features on the PCB 200. Accordingly the set of recesses and/or containing structures that are present on the second side 114 of the shelf member 110 includes recesses that are of at least two different depths, for example three different depths, in order to match the different dimensions of the components 104 on the PCB 200. Forming the recesses in this way allows the shelf member 110 to be manufactured in a time and cost effective manner.

Some or all of the electronic components 104 as well as the tracks may be located on one side, i.e. the surface 106 of the PCB 102 so that those components 104 are received within, and protected by, the shelf member 110 once assembled. In some embodiments the components 104 of the PCB 102 are surface-mounted. However, in some embodiments components also reside on an underside 120 of the PCB. For example, where the PCB 102 forms part of an RFID reader, an antenna controller and/or one or more connectors are arranged on the underside 120 for easy access. In this embodiment, the underside 120 may have a protective coating such as a solder resist coating, and/or a protective cover, for example, the components on the underside 120 may be enclosed in a protective box (not shown) attached to the underside 120 of the PCB 102.

The shelf member 110 has a structure (the structure including e.g. plastic, compact laminate, thermosetting plastic, thermoplastic or other suitable material) that has radio frequency (RF) properties such that operation of an RFID antenna positioned within the shelf 100 is not affected by the material properties of the shelf member 110. For example, suitable RF properties for the material of the shelf member 110 includes having a low dielectric constant, being non conducting or having a low conductivity (high resistivity), having little or no effect on the tuning or loss of the antenna, and/or resulting in a change of less than 30% in the power received by the antenna.

Recesses 116 corresponding to a negative of the circuit board topography are worked into the second side 114 of the shelf member 110 so that when the surface 106 of the PCB 102 is attached to the second side 114 of the shelf member 110, the electronic components 104 are received within the recesses 116 of the shelf member 110.

In FIG. 1B of the drawings, the shelf member 110 is shown to be attached to the PCB 102 using screws 122. However it will be appreciated that any suitable attachment method may be used, such as glue, latches, etc.

In another embodiment illustrated in FIG. 1C of the drawings, the shelf 100 includes an additional protective layer 107. This layer 107 may include a sheet of plastic or other material with suitable RF properties such as having a low dielectric constant, being non conducting or having a low conductivity (high resistivity), having little or no effect on the tuning or loss of the antenna, and/or resulting in a change of less than 30% in the power received by the antenna.

The shelf member 110 and/or the protective layer 107 may include a material that is good grade (i.e. safe for incidental food contact) and/or chemically resistant to cleaning solvents used in food safe environments. When intended for use in low or high temperature environments, the material(s) of the shelf member 110 and/or the protective layer 107 may be selected to have a wide operating temperature range of so as to be used without fracture or excessive deformation.

In FIG. 1D the protective layer 107 is shown attached to the shelf member 110 and the PCB 102 using screws 122. Again it will be appreciated that any suitable attachment method may be used, such as glue, latches, etc.

FIG. 1E of the drawings illustrates yet a further embodiment of the shelf 100 that includes an additional protective layer 107. In this embodiment the size of the PCB 102 size is reduced around its perimeter which results in a gap 108 between the edge of the PCB and the edge of the shelf member 110 and the protective layer 107.

FIG. 1F illustrates the protective layer 107 attached to the shelf member 110 and the PCB102. The gap 108 around the perimeter is sealed by a sealing agent 109 such as glue. It will be appreciated that any suitable sealing method may be used, such as a filler, a gasket, etc. This edge sealing prevents the ingress of water or other contaminants into the region between the shelf member 110 and the PCB 102. Depending on the application, this sealing agent may be food grade (i.e. safe for incidental food contact), have a wide operating temperature range, and/or have mildew resistance.

The arrangements of FIGS. 1D and 1F show the PCB 102 being sandwiched between the shelf member 110 and the protective layer 107.

Where the shelf member 110 and the protective layer 107 are made of the same type of thermoplastic then plastic welding can be used as an effective method of sealing 109. Polypropylene sheet material is suitable for this purpose as it is both a thermoplastic and also readily available as a food grade material. This is beneficial where the shelves are to be used for storing food, medical samples and transfusion products such as blood or plasma. Additionally or alternatively the shelf member 110 and/or the protective layer 107 may include polyethylene, for example in the form of polyethylene sheets. Polyethylene is a food grade material that has a low glass transition temperature and can be used at low temperatures without becoming excessively brittle (e.g. below −100° C., for example at −120° C.).

Where the shelf member 110 is a thermosetting plastic such as a compact laminate, then a gap filling glue or filler agent may be used for sealing 109.

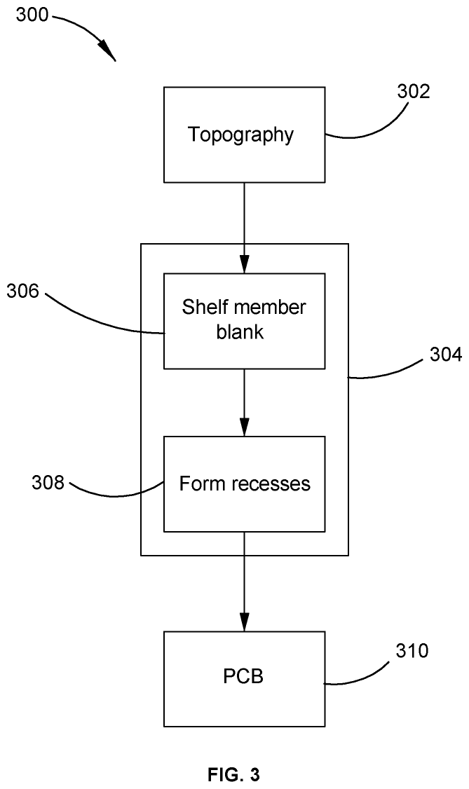

FIG. 3 of the drawings illustrates a method 300 of manufacturing a shelf 100 for use in electronic reading applications. At 302, the method 300 includes providing the circuit board topography having relief features defined by the plurality of electronic components 104 carried by the PCB 102 and standing proud of the surface 106 of the PCB 102. At 304, the method 300 includes providing the shelf member 110 with a first side 112 and an opposed, second side 114. The second side 114 of the shelf member 110 has recesses 116 corresponding to the negative of the circuit board topography.

In some embodiments said providing 304 includes firstly, at 306, providing a shelf member blank that has a pair of opposed surfaces and then, at 308, working one of the surfaces to form the recesses 116. In this way, the shelf member blank is worked so that the recesses 116 of the shelf member 110 correspond to the negative of the circuit board topography with the result that the plurality of electronic components 104 are receivable within the recesses 116 of the shelf member 110.

Working 308 one or more surfaces of the shelf member blank includes subtractive manufacturing, such as machining or milling, whereby portions of the material forming the shelf member (e.g. a compact laminate material or a plastic material) is cut into the required shape by a controlled material-removal process.

In some embodiments, the method also includes providing the PCB 102 and, at 310, marrying the surface 106 of the PCB 102 to the second side 114 of the shelf member 110 so that the electronic components 104 are received within the recesses 116 of the shelf member 110.

The method, shelf member, and shelf described herein benefit from the use of subtractive manufacturing such as machining the underside of shelving to fit an antenna against and into the underside. This reduces the expense of using hollowed out shelving that holds the antennas on the inside.

A plastic shell used for the shelf typically has a relatively low cost, however the tooling for the injection moulds may cost tens of thousands of dollars. The tooling can only be used for one design, and if any changes are made that require new tooling, this tooling cost is again applicable. For the method described herein no tooling is required, and instead the shelf is machined. Although machine time may also be costly, as the electronic components are relatively small (as can be seen in FIG. 2A and FIG. 2B), only small component cavities are required and the machining time is short. Accordingly, any change in electronic design can be easily translated into a new product without any additional setup or tooling cost or time.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A shelf for use in electronic reading applications, the shelf including:
a printed circuit board (PCB), the PCB carrying a plurality of electronic components which define a circuit board topography having relief features standing proud of a surface of the PCB; and
a shelf member having a first side and an opposed, second side, wherein the second side of the shelf member has recesses corresponding to a negative of the circuit board topography,
wherein the surface of the PCB is attached to the second side of the shelf member so that the electronic components are received within the recesses of the shelf member.

2. The shelf of claim 1, wherein the recesses are formed using subtractive manufacturing based on the negative of the circuit board topography.

3. The shelf of claim 1, wherein the PCB includes an RFID antenna.

4. The shelf of claim 1, further including a protective layer, wherein the PCB is sandwiched between the shelf member and the protective layer.

5. The shelf of claim 1, wherein the shelf member includes at least one of: a compact laminate material, a thermosetting plastic material, a thermoplastic.

6. A shelf member for use with a printed circuit board (PCB) carrying a plurality of electronic components which define a circuit board topography having relief features standing proud of a surface of the PCB,
the shelf member having a first side and an opposed, second side,
wherein the second side of the shelf member has recesses corresponding to a negative of the circuit board topography, and
wherein the second side of the shelf member is configured to be attached to the surface of the PCB so that the electronic components are received within the recesses of the shelf member.

7. The shelf member of claim 6, wherein the recesses are formed using subtractive manufacturing based on the negative of the circuit board topography.

8. The shelf member of claim 7, including a compact laminate material, and wherein the subtractive manufacturing includes machining of the compact laminate material.

9. The shelf member of claim 7, including a thermosetting plastic material, and wherein the subtractive manufacturing includes machining of the thermosetting plastic material.

10. The shelf member of claim 7, including a thermoplastic material, and wherein the subtractive manufacturing includes machining of the thermoplastic material.

11. The shelf member of shelf of claim 6, wherein the PCB is sandwiched between the shelf member and a protective layer.

12. A method of manufacturing a shelf member for use in electronic reading applications, the method including:
providing a circuit board topography having relief features defined by a plurality of electronic components carried by a printed circuit board (PCB) and standing proud of a surface of the PCB;
providing a shelf member blank having a pair of opposed surfaces; and
working one of the surfaces to form recesses corresponding to a negative of the circuit board topography so that the plurality of electronic components are receivable within the recesses of the shelf member.

13. The method of claim 12, wherein the working includes subtractive manufacturing of the one of the surfaces based on the circuit board topography.

14. A method of manufacturing a shelf for use in electronic reading applications, the method including:
providing a printed circuit board (PCB), the PCB carrying a plurality of electronic components which define a circuit board topography having relief features standing proud of a surface of the PCB;
providing a shelf member having a first side and an opposed, second side, wherein the second side of the shelf member has recesses corresponding to a negative of the circuit board topography; and
marrying the surface of the PCB to the second side of the shelf member so that the electronic components are received within the recesses of the shelf member.

15. The method of claim 14, wherein the PCB includes an RFID antenna.

16. The method of claim 14, wherein the shelf member includes at least one of: a compact laminate material, a thermosetting plastic material, and a thermoplastic material.

17. The method of claim 14, further including:
providing a shelf member blank having a pair of opposed surfaces; and
working one of the surfaces to form the recesses to provide the shelf member.

18. The method of claim 17 wherein the working includes using subtractive manufacturing based on the circuit board topography.
